(19) United States
(12) Patent Application Publication
(10) Pub. No.: US 2012/0252226 A1
(43) Pub. Date: Oct. 4, 2012

(54) PLASMA PROCESSING METHOD

(75) Inventors: Yoshiro KABE, Nirasaki City (JP); Takashi KOBAYASHI, Nirasaki City (JP); Ryota YONEZAWA, Nirasaki City (JP)

(73) Assignee: Tokyo Electron Limited, Tokyo (JP)

(21) Appl. No.: 13/426,066

(22) Filed: Mar. 21, 2012

(30) Foreign Application Priority Data
Mar. 31, 2011 (JP) 2011-080620

(51) Int. Cl. H01L 21/316

(52) U.S. Cl. 438/772; 257/E21.283

(57) ABSTRACT

A plasma processing method performs a plasma oxidation on a substrate, on which a trench is formed after an oxide film is formed, by using a plasma processing apparatus for plasma-processing an object by using microwave plasma. In the plasma processing method, the substrate is mounted on a mounting table to which an ion attraction high frequency voltage is applied, and the plasma oxidation is performed while applying the ion attraction high frequency voltage to the substrate. Further, a process gas used in the plasma oxidation is a mixture of a rare gas having smaller atomic weight than that of argon gas, and oxygen gas, and the plasma processing is performed at a pressure of 6.7 to 133 Pa in a depressurized chamber.

### FIELD OF THE INVENTION

The present invention relates to a plasma processing method for plasma-processing an object.

### BACKGROUND OF THE INVENTION

With recent miniaturization and high integration of semiconductor devices, instead of LOCOS (Local Oxidation of Silicon) by a field oxide film which has been conventionally used for isolation between devices formed on a substrate, so-called STI (Shallow Trench Isolation) for forming a trench between devices and forming an oxide film in the trench for device isolation is being in wide use.

As methods for forming an oxide film in a trench in a STI technique, there have been known a thermal oxidation method for heating a silicon substrate and a plasma oxidation method for plasma-oxidizing a surface of a silicon substrate with plasma (see, e.g., Japanese Patent Application Publication No. 2004-349546).

The plasma oxidation method is typically performed in a plasma processing apparatus for generating plasma using, typically, a microwave or the like. In the plasma processing apparatus, a microwave generated by a microwave oscillator is introduced into a process chamber through a waveguide, an antenna and a dielectric window and is used to generate plasma of argon (Ar) gas and oxygen gas supplied into the process chamber. The oxygen gas plasma oxidizes a surface of the silicon substrate mounted on a substrate mounting table, thereby forming a silicon oxide film on the surface of the silicon substrate.

In this connection, in forming an oxide film in the above-mentioned trench, a method has been examined which suppresses oxidation of a side of the trench and makes an oxide film formed on the side of the trench thin. This is because, although thickness of the oxide film is typically several nm to ten and several nm, a trench (channel length (width) in device formation) occupied in a silicon substrate and a percentage (thickness) of an oxide film formed in the trench have been greatly problematic with miniaturization of devices.

When an oxide film is formed in a trench by using plasma processing, in order to make an oxide film on the side of the trench thin, it is effective to perform the plasma processing under low pressure conditions. However, a micro loading effect due to miniaturization makes oxidation in the bottom of the trench difficult, which requires much time to form an oxide film having desired thickness on the bottom of the trench. As a result, the oxide film on the side of the trench becomes also thick. In addition, there is a problem that the thickness of the oxide film on the side of the trench is not uniform in a height direction.

To overcome this problem, a method of applying a bias high frequency voltage for ion attraction to a lower part of a substrate mounting table is typically being used. Ions in plasma are attracted to the substrate by this bias voltage, thereby facilitating the oxidation of the bottom of the trench and making the oxide film in the side of the trench thin.

However, when an ion attraction voltage is applied to a silicon substrate W having a thermal oxide film 100 and a trench 101 formed therein as shown in FIG. 6A and then plasma processing by argon gas and oxygen gas is performed for the silicon substrate W, it has been confirmed that an edge of a pattern of the thermal oxide film 100 above the trench 101 is etched by sputtering, thereby deforming the thermal oxide film 100 formed on the silicon substrate W. In addition, it has been confirmed that fluxes (floating matters) 102 of the sputtered thermal oxide film 100 are deposited on the bottom of the trench 101 and apparent thickness of an oxide film 103 formed by the plasma processing on the bottom of the trench 101 increased over that of the actually formed oxide film 103. In this case, since it is difficult to make correct measurement of the thickness of the oxide film 103 on the bottom of the trench 101 due to the fluxes (floating matters) 102, there occurs a problem that whether or not the plasma processing is properly performed cannot be estimated.

### SUMMARY OF THE INVENTION

In view of the above, the present invention provides a plasma processing method for forming an oxide film on a substrate having a trench by using plasma, which is capable of thinning an oxide film formed on the side of the trench and preventing an edge of a pattern formed above the trench from being etched.

In accordance with an aspect of the present invention, there is provided a plasma processing method for performing a plasma oxidation on a substrate, on which a trench is formed after an oxide film is formed, by using a plasma processing apparatus for plasma-processing an object by using microwave plasma, wherein: the substrate is mounted on a mounting table to which an ion attraction high frequency voltage is applied; the plasma oxidation is performed while applying the ion attraction high frequency voltage to the substrate; a process gas used in the plasma oxidation is a mixture of a rare gas having smaller atomic weight than that of argon gas, and oxygen gas; and the plasma processing is performed at a pressure of 6.7 to 133 Pa in a depressurized chamber.

### BRIEF DESCRIPTION OF THE DRAWINGS

The objects and features of the present invention will become apparent from the following description of embodiments, given in conjunction with the accompanying drawings, in which:

FIG. 1 is a schematic vertical sectional view showing an exemplary configuration of a plasma processing apparatus for performing a plasma processing method according to an embodiment of the present invention;

FIGS. 2A to 2C are schematic vertical sectional views for explaining a process of forming an oxide film in a trench by using the plasma processing method according to the embodiment of the present invention, FIG. 2A showing a wafer formed with the trench, FIG. 2B showing a state of oxidizing the trench by oxygen radicals, and FIG. 2C showing a state where the oxide film is formed in the trench;

FIG. 3 is a graph showing a relationship between an internal pressure of a process chamber and an oxide film formation rate;

FIGS. 4A to 4D are vertical sectional views showing a state of the vicinity of a thermal oxide film after plasma oxidation;

FIGS. 5A to 5D are vertical sectional views showing a state of an oxide film formed in the trench by plasma oxidation; and

FIGS. 6A and 6B are schematic vertical sectional views showing an oxide film forming process according to a conventional plasma processing method.

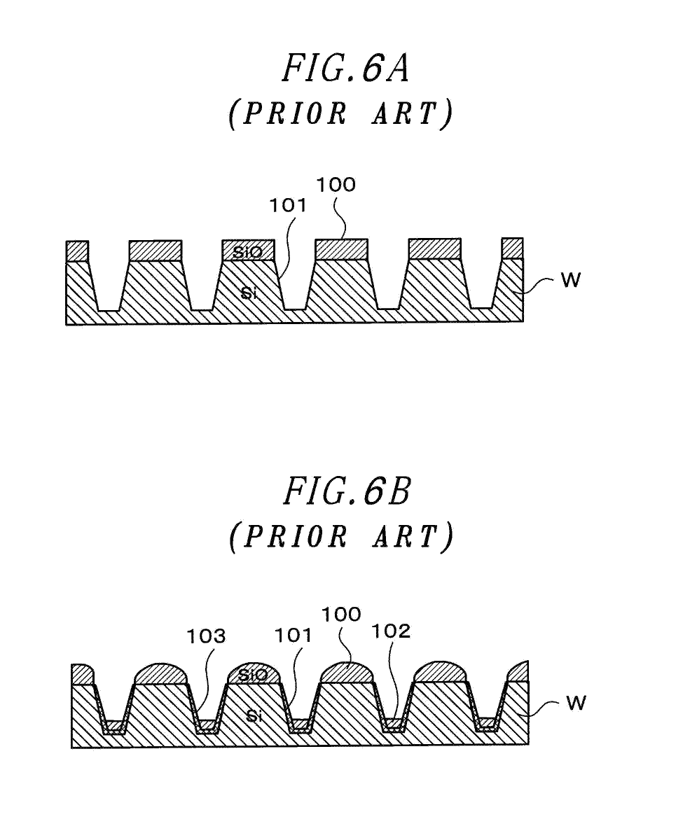

### DETAILED DESCRIPTION OF THE EMBODIMENTS

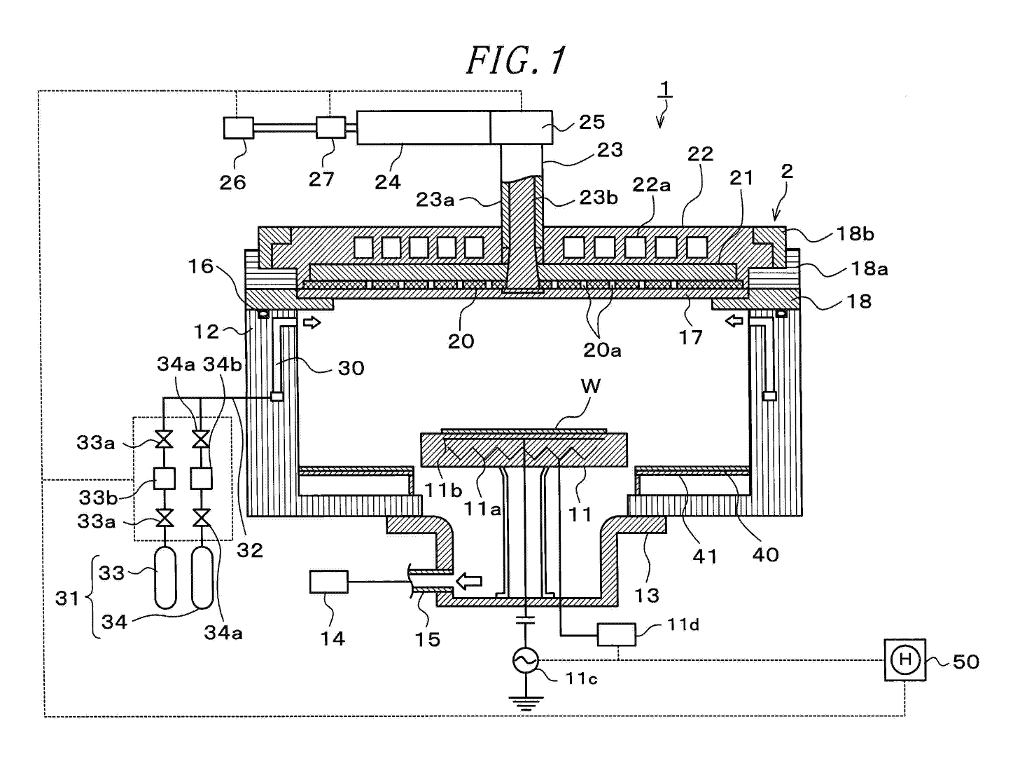

Hereinafter, an embodiment of the present invention will be described with reference to the accompanying drawings. FIG. 1 is a schematic vertical sectional view showing an exemplary configuration of a plasma processing apparatus 1 according to an embodiment of the present invention. The plasma processing apparatus 1 employs a so-called radial line slot antenna system in which an electric field is generated in the apparatus by a microwave and a process gas supplied into the apparatus is converted into plasma to perform an etching process or the like on a wafer W. A silicon substrate is used as the wafer W.

The plasma processing apparatus 1 includes a process chamber 12 having therein a susceptor 11 as a support for supporting the wafer W. The susceptor 11 is made of, for example, heat insulating ceramic. The susceptor 11 includes therein a heater 11a for controlling a surface temperature of the wafer W and a bias electrode 11b for applying a plasma attraction high frequency voltage. The bias electrode 11b is made of a material having substantially the same coefficient of thermal expansion as the ceramic of the susceptor 11, such as, for example, tungsten (W), molybdenum (Mo) or the like. The bias electrode 11b is connected to an AC power source 11c for generating the plasma attraction high frequency voltage. The heater 11a is connected to a heater power source 11d. An exhaust chamber 13 as an exhaust part to exhaust the interior of the process chamber 12 is provided at the bottom of the process chamber 12. An exhaust pipe 15 connected to an exhaust device 14 such as a vacuum pump or the like is connected to the exhaust chamber 13.

An opening is formed in the upper part of the process chamber 12 to correspond to the wafer W on the susceptor 11. A microwave supplying part 2 is arranged in the opening to block the opening and supply a microwave into the process chamber. The process chamber 12 is air-tightly closed by a lid member 18 which supports a dielectric window 17 made of quartz or Al₂O₃ and serves to open and close the process chamber 12 through seal material 16 such as an O-ring. An annular fixing member 18a having an L-like section is provided on the lid member 18 and the lid member 18 and the fixing member 18a are fixed together by means of, for example, joining members (not shown) such as bolts or the like. An L-like annular pressing member 18b having an L-like section rotated by 90 degrees is provided on the fixing member 18a and the pressing member 18b, the fixing member 18a and a cover plate 22 are fixed together by means of joining members (not shown).

An antenna 20 is arranged on the top (outer side) of the dielectric window 17. The antenna 20 is formed of a thin disc made of conductive material, for example, metal such as copper, aluminum, nickel or the like. In this embodiment, the antenna 20 is a so-called radial line slot antenna having a plurality of slots 20a formed concentrically on a surface of the antenna. Each slot 20a has a substantially rectangular shape and the adjacent slots are arranged perpendicular to each other in a “T” shape. Length and arrangement interval of the slots 20a depend on a wavelength of a supplied microwave.

A dielectric plate 21 made of quartz, alumina, aluminum nitride or the like is arranged on the antenna 20. The dielectric plate 21 serves as a wave retardation plate. The cover plate 22 made of a conductive material such as aluminum or the like is arranged on the dielectric plate 21 to cover the dielectric plate 21. The antenna 20 has an outer peripheral portion held by the cover plate 22. A coolant path 22a through which a coolant flows is formed in the cover plate 22 to cool the antenna 20, the dielectric plate 21 and the dielectric window 17. A co-axial waveguide 23 is connected to the center of the cover plate 22. A microwave generator 26 is connected to the top end of the co-axial waveguide 23 through a rectangular waveguide 24 and a mode converter 25.

The microwave generator 26 is installed in the outside of the process chamber 12 and can generate a microwave having a frequency of, e.g., 2.45 GHz. An impedance matching unit 27 for impedance matching of the microwave is connected to the microwave generator 23 via the mode converter 25. The co-axial waveguide 23 is composed of an outer conductor 23a and an inner conductor 23b which is connected to the antenna 20. With this configuration, the microwave generated from the microwave generator 26 propagates through the impedance matching unit 27, the rectangular waveguide 24, the mode converter 25 and the co-axial waveguide 24, and is then compressed into a wave having a shorter wavelength in the dielectric plate 21 acting as the wave retardation plate. Then, a circularly polarized microwave emitted from the antenna 20 passes through the dielectric window 17 to be introduced into the process chamber 12.

A gas supply hole 30 through which a plasma generation gas is supplied is formed in an upper portion of the process chamber 12. In this embodiment, the gas supply hole 30 is provided in plural along the inner circumference of the process chamber 12, for example. A gas supply pipe 32 connected to a gas supply source 31 provided in the outside of the process chamber 12 is connected to the gas supply hole 30. In this embodiment, the gas supply source 31 includes a rare gas supply source 33 and an oxygen gas supply source 34 which are connected to the gas supply hole 30 via valves 33a and 34a and mass flow controllers 33b and 34b, respectively. Flow rates of the gases supplied from the gas supply source 31 are controlled by the mass flow controllers 33b and 34b, respectively. In this embodiment, the gas supply source 31 stores as a process gas helium (He) gas or neon (Ne) gas which is a rare gas having lower atomic weight than that of argon gas and oxygen gas used for plasma oxidation of the wafer W.

A gas baffle plate 40 made of, for example, quartz is disposed around the susceptor 11 within the process chamber 12. The bottom of the gas baffle plate 40 is supported by a support member 41 made of metal such as aluminum or the like.

The plasma processing apparatus 1 is also provided with a controller 50. The controller 50 is, for example, a computer and includes a program storage (not shown). The program storage stores therein programs for operating the plasma processing apparatus 1 by controlling components such as the microwave generator 26, the impedance matching unit 27 and the mass flow controller 33. The programs may be those stored in a computer readable storage medium H such as a hard disk (HD), a flexible disk (FD), a compact disk (CD), a magnetic-optical disk (MO), a memory card or the like and installed from the storage medium H to the controller 50.

Next, a plasma processing method performed by the plasma processing apparatus 1 of this embodiment will be described.

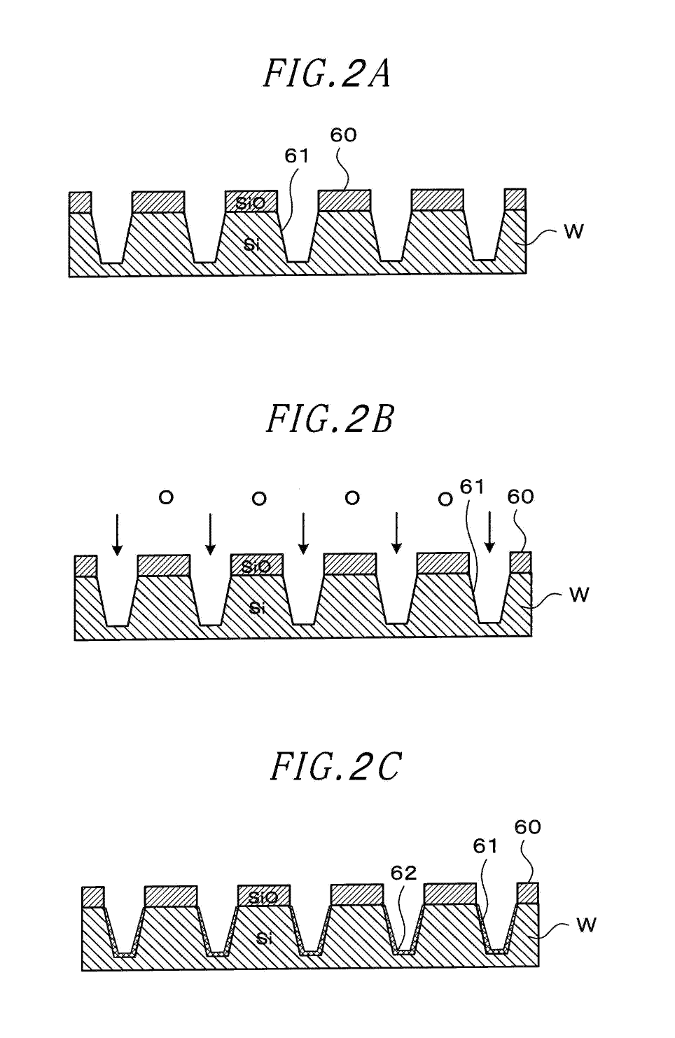

In performing the plasma processing, as shown in FIG. 2A, a wafer W is first prepared on a surface of which a thermal oxide film 60 is formed and a trench 61 is then formed therein. Subsequently, the wafer W is loaded on the susceptor 11. During the plasma processing, the surface of the wafer W is heated to, for example, 465° C. by the susceptor 11 and an ion attraction high frequency voltage with power of 600 W is applied from the AC power source 11c to the wafer W. Thereafter, the interior of the process chamber 12 is exhausted by the exhaust device 14 to set the internal pressure of the process chamber 12 to a predetermined pressure, for example, 40 Pa. Temperature of the wafer W is preferably ranges from room temperature to 600° C., more preferably from 200° C. to 600° C.

Next, helium gas and oxygen gas are introduced into the process chamber 12 through the gas supply hole 30. At this time, a flow rate of helium gas is, for example, 124 sccm and a flow rate of oxygen gas is, for example, 60.8 sccm.

Thereafter, a microwave is supplied from the microwave generator 26 into the process chamber 12 via the co-axial waveguide 23. The supplied microwave has a frequency of 2.45 GHz and power of 1000 to 4000 W. In this embodiment, a microwave of 4000 W is introduced into the process chamber 12 via the dielectric plate 21, the antenna 20 and the dielectric window 17. The helium gas and the oxygen gas in the process gas 12 are excited by high density microwave plasma and atomic oxygen (O(1D) oxygen radicals) and O₂_{⁺} are formed by the excitation of the helium gas. This atomic oxygen reaches a surface of the trench 61 of the wafer W, as shown in FIG. 2B. Accordingly, an oxide film 62 is formed on the surface of the trench 61, as shown in FIG. 2C.

In the above-described plasma processing method, the helium gas, which is rare gas having lower atomic weight than that of argon gas conventionally used as process gas, is used to perform the plasma oxidation on the wafer W while applying the ion attraction high frequency voltage to the wafer W, and the plasma oxidation is performed under the condition of a low pressure of 40 Pa in a depressurized container such as the process chamber 12. Accordingly, while attracting oxygen ions into the trench 61 to facilitate the oxidation of the bottom of the trench 61, the oxide film 62 on the side of the trench 61 becomes thinned by suppressing the oxidation of the side of the trench 61. In addition, ions of the helium gas which is rare gas having lower atomic weight than that of the argon gas prevent an edge of the thermal oxide film 60 formed above the trench 61 from being etched.

Although in the above embodiment the plasma processing has been performed with the internal pressure of the process chamber 12 set to 40 Pa, the internal pressure of the process chamber 12 ranges preferably from 6.7 to 133 Pa, more preferably from 6.7 to 93 Pa. Accordingly, the internal pressure may be variously set within the above range.

Although in the above embodiment the plasma processing has been performed using the mixture of the helium gas and the oxygen gas supplied in the process chamber 12, hydrogen gas may be added to the helium gas and the oxygen gas. In this case, the added hydrogen gas can terminate dangling bonds of the surface of the wafer W and stabilize an interface between the surface of the trench 61 of the wafer W and the silicon oxide film 62 formed on the surface of the trench 61. A flow rate of the hydrogen gas ranges preferably from 1 to 100 ml/min (sccm), more preferably from 1 to 50 ml/min (sccm), even more preferably 15.2 sccm.

### EXAMPLES

For the purpose of measurement of an effect of the plasma processing of the present invention, comparison tests were carried out for a case where the wafer W having the thermal oxide film 60 and the trench 61 formed thereon as shown in FIG. 2A was subjected to the plasma oxidation using a mixture of helium gas and oxygen gas and a case where the wafer W was subjected to the plasma oxidation using a mixture of argon gas and oxygen gas. For the case of the mixture of helium gas and oxygen gas, two cases were carried out; one where low pressure plasma oxidation was performed for 130 seconds under conditions where helium gas, oxygen gas and hydrogen gas were supplied into the process chamber 12 at flow rates of 124 ml/min (sccm), 60.8 ml/min (sccm) and 15.2 ml/min (sccm), respectively, and the internal pressure of the process chamber 12 was set to 40 Pa (Example 1), and the other where high pressure plasma oxidation was performed for 270 seconds under conditions where helium gas, oxygen gas and hydrogen gas were supplied into the process chamber 12 at flow rates of 150 ml/min (sccm), 40 ml/min (sccm) and 10 ml/min (sccm), respectively, and the internal pressure of the process chamber 12 was set to 533 Pa (Example 2). In Examples 1 and 2, targeted thickness of the oxide film 62 on the top of the trench was set to 11 nm. Microwave supply power and bias high frequency voltage power were set to 4000 W and 600 W, respectively, and temperature of the wafer W was set to 465° C.

As comparative examples, for the case of the mixture of argon gas and oxygen gas, two cases were carried out: one where low pressure plasma oxidation was performed for 215 seconds under conditions where argon gas, oxygen gas and hydrogen gas were supplied into the process chamber 12 at flow rates of 150 ml/min (sccm), 40 ml/min (sccm) and 10 ml/min (sccm), respectively, the internal pressure of the process chamber 12 was set to 40 Pa, and microwave power of 1200 W was supplied (Comparative Example 1), and the other where high pressure plasma oxidation was performed for 360 seconds under the same conditions as Comparative Example 1 except that the internal pressure of the process chamber 12 was set to 533 Pa and microwave power of 4000 W was supplied (Comparative Example 2). In Comparative Examples 1 and 2, targeted thickness of the oxide film 62 on the top of the trench was set to 8 nm. Bias high frequency voltage power was set to 600 W and temperature of the wafer W was set to 465° C.

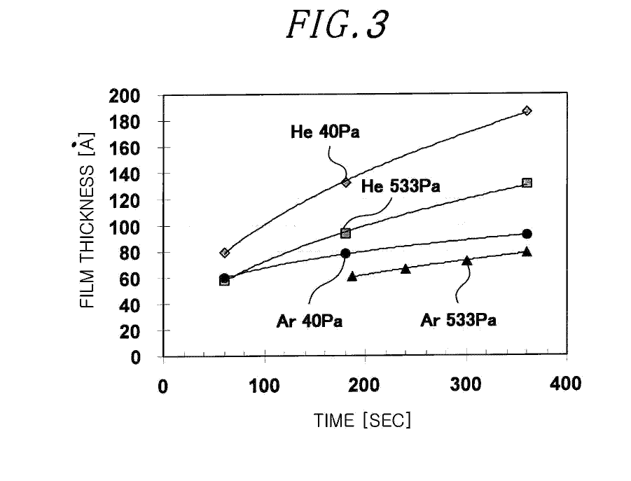

In addition, film formation rates of oxide films for a case where plasma oxidation was performed on wafers W having no trench 61 formed thereon under the same conditions as Examples 1 and 2 and Comparative Examples 1 and 2 were obtained. The results are shown in FIG. 3. In FIG. 3, the vertical axis represents thickness (Angstrom Å) of an oxide film and the horizontal axis represents processing time. It can be seen from the results of FIG. 3 that a lower internal pressure of the process chamber 12 provides a higher film formation rate. Accordingly, in a process of low pressure conditions, helium gas which is rare gas having lower atomic weight than that of argon gas can be used for high oxidation rate processing, which can result in reduction of process time.

In the above-described Examples 1 and 2 and Comparative Examples 1 and 2, the processing time is set depending on the film formation rates shown in FIG. 3. More specifically, processing times for Examples 1 and 2 whose target film thickness is 11 nm were obtained as 130 seconds and 270 seconds, respectively, from FIG. 3. Similarly, processing times for Comparative Examples 1 and 2 whose target film thickness is 8 nm were obtained as 215 seconds and 360 seconds, respectively, from FIG. 3.

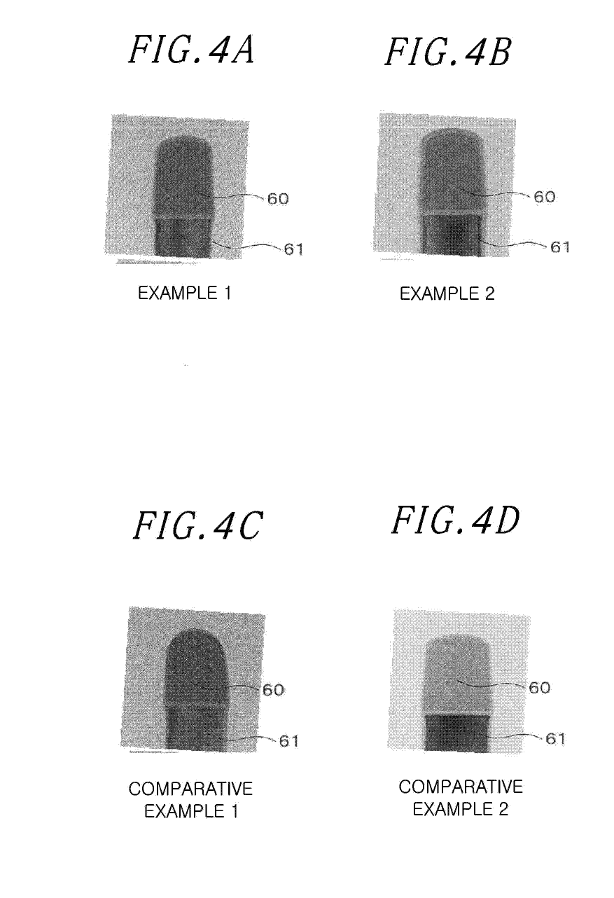

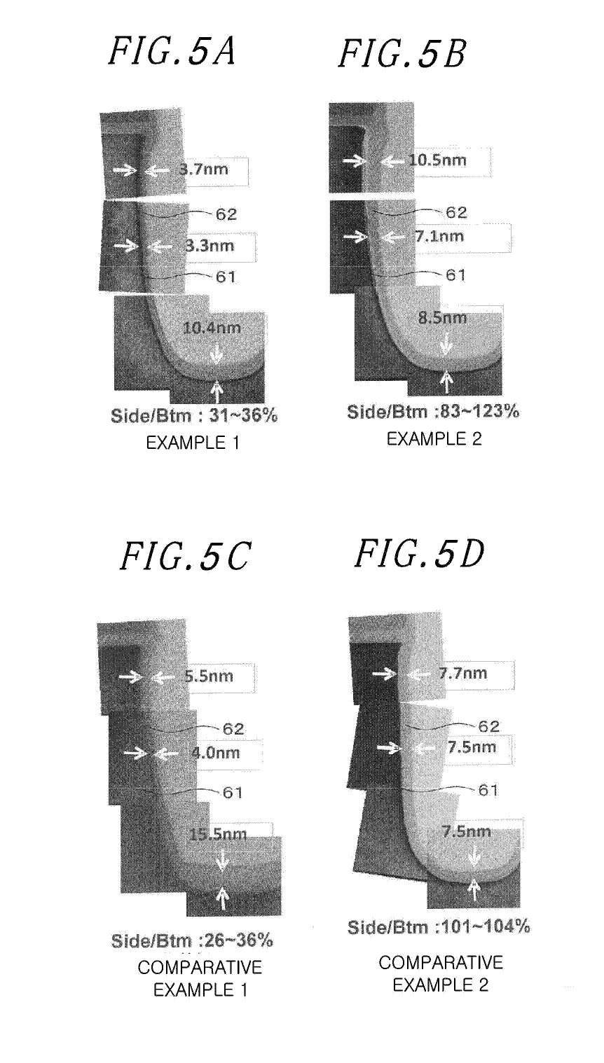

Results of confirmation test are shown in FIGS. 4A to 5D. FIGS. 4A and 4B show states of the vicinity of a thermal oxide film 60 above the trench 61 after plasma oxidation according to Examples 1 and 2, respectively. FIGS. 4C and 4D show sections of the thermal oxide film 60 above the trench 61 after plasma oxidation according to Comparative Examples 1 and 2, respectively.

As can be seen from FIGS. 4A to 4D, in Comparative Example 1 using the argon gas, an edge of the thermal oxide film 60 is etched to be deformed, i.e., rounded by sputtering. On the other hand, in Examples 1 and 2 using the helium gas which is rare gas having lower atomic weight than that of the argon gas, an edge of the thermal oxide film 60 is suppressed from being etched to be deformed by sputtering. In addition, in Comparative Example 2, there occurs no deformation in the thermal oxide film 60, which is believed because amount of ions and a sputtering effect are reduced due to the high pressure conditions.

FIGS. 5A and 5B show states of an oxide film 62 formed in a trench 61 by plasma oxidation in Examples 1 and 2. FIGS. 5C and 5D show states of an oxide film 62 formed in a trench 61 by plasma oxidation in Comparative Examples 1 and 2.

As shown in FIG. 5A, in Example 1, it could be conformed that thickness of the oxide film 62 on the bottom of the trench 61 was 10.4 nm for the targeted thickness of 11 nm and the substantially same film formation rate as the result of FIG. 3 was achieved. In addition, it was confirmed that thickness of the oxide film 62 on the side of the trench 61 was 3.3 nm to 3.7 nm and the oxide film 62 on the side of the trench 61 was advantageously thinned. On the other hand, in Example 2, as shown in FIG. 5B, the film thickness was 8.5 nm smaller than the targeted thickness. It is believed that this is because a micro loading effect occurs even under the high pressure conditions as can be seen from the fact that the thickness of the oxide film on the side is different in a height direction. In Example 2, the thickness of the oxide film 62 on the side of the trench 61 was 7.1 nm to 10.5 nm. It is inferred that amount of ions is reduced due to the relatively large pressure of 533 Pa in Example 2 so that the oxide film 62 on the side of the trench 61 cannot be thinned.

Next, in Comparative Example 1, as shown in FIG. 5C, the thickness of the oxide film 62 on the bottom of the trench 61 was 15.5 nm significantly exceeding the targeted thickness of 8 nm. It is considered that this is because the apparent thickness of the oxide film is increased as fluxes (floating matters) of the thermal oxide film 60 on the wafer W etched by sputtering are deposited on the bottom of the trench 61, as described above. Like Example 1, the side of the trench 61 was thinned. In Comparative Example 2, as shown in FIG. 5D, the thickness of the oxide film 62 on the bottom of the trench 61 was 7.5 nm for the targeted thickness of 8 nm, which is substantially desired thickness. However, since a pressing pressure is a relatively large pressure of 533 Pa, the film thickness on the side of the trench 61 is as large as 7.5 nm to 7.7 nm and, like Example 2, the oxide film 62 on the side of the trench 61 cannot be thinned.

This is because the helium atomic weight is 4.0 which is about 1/10 of the argon atomic weight of 39.95. That is, when plasma is generated, since helium ions are light, sputtering to an edge, that is, a side wall, of the thermal oxide film 60 becomes weak. In addition, oxide film formed on the side wall of the trench 61 becomes thin since the side wall is oxidized with atomic oxygen. Since oxygen ions are introduced into the trench, oxidation of the bottom of the trench is accelerated to provide the same film thickness as the top of the trench. On the contrary, if argon gas is used, since argon ions are heavy, sputtering to the side wall is high and the formed oxide film is sputtered and deposited on the bottom of the trench 61, thereby increasing film thickness which is double as large as that of the top of the trench. Accordingly, helium or neon gas which is rare gas having lower atomic weight than that of argon gas is preferably used.

As can be seen from the above results, when the plasma processing is performed by using the mixture of helium gas and oxygen gas under the low pressure conditions according to the present invention, the oxide film 62 on the side of the trench 61 formed in the wafer W can be thinned and a pattern of the thermal oxide film 60 or the like formed above the trench 61 can be suppressed from being etched by sputtering.

As described above, the internal pressure of the process chamber 12 in plasma processing ranges favorably from 6.7 to 133 Pa, preferably from 6.7 to 93 Pa, more preferably from 20 to 67 Pa. Flow rates of helium gas and oxygen gas range preferably from 50 to 1000 ml/min (sccm), more preferably from 100 to 500 ml/min (sccm), desirably from 100 to 190 ml/min (sccm). A flow rate of oxygen gas ranges preferably from 5 to 500 ml/min (sccm), more preferably from 10 to 300 ml/min (sccm), desirably from 10 to 100 ml/min (sccm). Accordingly, a film formation rate higher than that obtained when argon gas is used can be obtained, thereby achieving improvement of a throughput.

While the invention has been shown and described with respect to the embodiments, the present invention is limited to the disclosed embodiments but may be applied to ICP plasma, magnetron plasma and surface wave plasma. It will be understood by those skilled in the art that various changes and modification may be made without departing from the scope of the invention as defined in the following claims.

What is claimed is:

1. A plasma processing method for performing a plasma oxidation on a substrate, on which a trench is formed after an oxide film is formed, by using a plasma processing apparatus for plasma-processing an object by using microwave plasma, wherein:
the substrate is mounted on a mounting table to which an ion attraction high frequency voltage is applied;
the plasma oxidation is performed while applying the ion attraction high frequency voltage to the substrate;
a process gas used in the plasma oxidation is a mixture of a rare gas having smaller atomic weight than that of argon gas, and oxygen gas; and
the plasma processing is performed at a pressure of 6.7 to 133 Pa in a depressurized chamber.

2. The plasma processing method of claim 1, wherein the rare gas having smaller atomic weight than that of argon gas is helium gas or neon gas.

3. The plasma processing method of claim 1, wherein the rare gas having smaller atomic weight than that of argon gas is helium gas, a flow rate of the helium gas ranges from 100 to 500 ml/min (sccm) and a flow rate of the oxygen gas ranges from 10 to 300 ml/min (sccm).

4. The plasma processing method of claim 1, wherein temperature of the substrate in the plasma processing ranges from 200 to 600° C.

5. The plasma processing method of claim 1, wherein hydrogen gas is contained in the process gas for the plasma oxidation and a flow rate of the hydrogen gas ranges from 1 to 100 ml/min (sccm).

6. The plasma processing method of claim 1, wherein power of the microwave ranges from 1000 to 4000 W.
